(19) United States
(12) Patent Application Publication
(10) Pub. No.: US 2019/0378657 A1
(43) Pub. Date: Dec. 12, 2019

(54) MULTIPLE LAYER CYLINDRICAL CAPACITOR

(71) Applicant: QUALCOMM Incorporated, San Diego, CA (US)

(72) Inventors: Ye LU, San Diego, CA (US); Junjing BAO, San Diego, CA (US); Bin YANG, San Diego, CA (US)

(21) Appl. No.: 16/004,828

(22) Filed: Jun. 11, 2018

(51) Int. Cl. H01G 4/30; H01G 4/005; H01G 4/018; H01L 49/02

(52) U.S. Cl. CPC H01G 4/30; H01L 28/60; H01G 4/018; H01G 4/005

(57) ABSTRACT

Aspects generally relate to multilayer capacitor structures formed in vias in a substrate of an integrated circuit. The multilayer cylindrical capacitor includes multiple cylindrical conductive layers formed in the via and separated by multiple cylindrical insulating layers between the plurality of cylindrical conductive layers. The cylindrical conductive layers form plates of the multilayer cylindrical capacitor.

### BACKGROUND

### I. Field of the Disclosure

Aspects of the disclosure relates generally to capacitors, and in particular, multiple layer or multilayer cylindrical capacitors formed in a via, a through silicon via (TSV), and a super via.

### II. Background

Capacitors are widely used in integrated circuits (IC). A typical IC includes a semiconductor substrate where active devices are formed. Above the substrate is an insulation layer, and then multiple metal layers separated by interlayer insulating layers. Portions of the metal layers are coupled together, and to the active devices by vias through the interlayer insulating layers. The capacitor structures are typical formed using the metal layers and active devices. In advanced ICs some typically types of capacitor structures include the metal-insulator-metal (MIM) capacitor structure, the metal-oxide-metal (MOM) capacitor structure, and the metal-oxide-silicon (MOS) capacitor structure.

FIG. 1A is a diagram of a MIM capacitor structure. As seen in FIG. 1A, a first plate of the MIM capacitor structure is formed using a portion of a metal layer 104, and a second plate of the capacitor is formed using a portion of a second metal layer 108. The first and second plates of the capacitor are separated from each other by an interlayer insulating layer 112, thereby forming the MIM capacitor.

FIG. 1B is a diagram of a MOM capacitor structure. As seen in FIG. 1B, a first plate, or finger, of the MOM capacitor structure is formed from portions of multiple metal layers 120, 122, 124, and 126 connected by vias (not shown). A second plate, or finger, of the MOM capacitor structure is formed from portions of multiple metal layers 130, 132, 134, and 136 connected by vias (not shown). Insulating layers formed between, and around, the portions of the metal layers forming the first and second plates, or fingers, separate the plates, thereby forming the MOM capacitor. In the example of FIG. 1B, a third plate, or finger, of the MOM capacitor structure is formed from portions of multiple metal layers 140, 142, 144, and 146 connected by vias (not shown). Insulating layers formed between, and around, the portions of the metal layers forming the second and third plates, or fingers, separate the plates, thereby forming another MOM capacitor.

FIG. 1C is a diagram of a MOS capacitor structure. As shown in FIG. 1C a first portion of a metal layer 150 is coupled to a gate 152 of a MOSFET transistor 154 formed in the substrate 156. As is well known in the art, the gate 152 of the MOSFET transistor 154 is separated, by an insulator 158, from a channel 160 between a source 162 and a drain 164 of the MOSFET transistor 154. In this configuration, the gate 152 forms one plate of the capacitor and the channel/source/drain 160, 162, and 164 respectively, form the other plate of the capacitor.

Other types of capacitors include coaxial via capacitors. FIG. 2A is diagram of a through via coaxial capacitor. As shown in FIG. 2A there is a via 204 formed through a substrate 206. On the outer walls of the via 204 a first electrode 210 is formed. On the surface of the first electrode 210 an insulating layer 212 is formed. The remaining portion of the via 204 is filled with a second electrode 214. The first electrode 210, insulating layer 212, and second electrode 214 for the coaxial via capacitor.

FIG. 2B is diagram of a blind via coaxial capacitor. As shown in FIG. 2B there is a blind via 224 formed in a substrate 226. The blind via 224 extends through only a portion of the substrate 226. On the outer walls of the via 224 a first electrode 230 is formed. On an inner surface of the first electrode 230 an insulating layer 232 is formed. The remaining portion of the via 224 is filled with a second electrode 234. The first electrode 230, insulating layer 232, and second electrode 234 for the blind via coaxial capacitor.

The MIM, MOM, and MOS capacitors occupy significant amounts of area of an IC. The coaxial via capacitors have low capacitance density providing small amounts of capacitance. As the size of ICs decrease there is a need for capacitors that occupy less IC area and offer increased capacitor density.

### SUMMARY OF THE DISCLOSURE

The described aspects generally relate to a multilayer cylindrical capacitor structure formed in a via.

In an embodiment, a multilayer cylindric capacitor includes a substrate and a via formed in the substrate. A first cylindrical conductive layer formed on an inner wall of the via, a first cylindrical insulating layer formed on an inner surface of the first cylindrical conductive layer, a second cylindrical conductive layer formed on an inner surface of the first cylindrical insulating layer, a second cylindrical insulating layer formed on an inner surface of the second cylindrical conductive layer; and a third cylindrical conductive layer formed on an inner surface of the second cylindrical insulating layer.

The cylindrical conductive layers of the multilayer cylindrical capacitor can be metal or other conductive material metal. The cylindrical insulating layers of the multilayer cylindrical capacitor can be a dielectric, such as a high k dielectric. In addition, the third cylindrical conducting layer can fill the remaining portion of the via.

The via can be a through silicon via (TSV), a blind via, or a Super via. In addition, the multilayer cylindrical capacitor can be coupled with other components, for example, a MOM capacitor, a MIM capacitor, or a MOS capacitor.

In another embodiment, a multilayer cylindric capacitor includes a via formed in a substrate, and a plurality of cylindrical conductive layers and a plurality of cylindrical insulating layer formed inside the via, wherein the plurality of cylindrical conductive layers are separated by the plurality of cylindrical insulating layers.

The cylindrical conductive layers of the multilayer cylindrical capacitor can be metal. In addition, cylindrical insulating layers of the multilayer cylindrical capacitor can be a dielectric, such as a high k dielectric.

The via can be a through silicon via (TSV), a blind via or a Super via. In addition, the multilayer cylindrical capacitor can be coupled with other components, for example, a MOM capacitor, a MIM capacitor, or a MOS capacitor. another component coupled to the multilayer cylindrical capacitor.

In another embodiment, a method of fabricating a multilayer cylindric capacitor includes forming a via in a substrate. Forming a plurality of cylindrical conductive layers and a plurality of cylindrical insulating layer inside the via, wherein the plurality of cylindrical conductive layers are separated by the plurality of cylindrical insulating layers.

The cylindrical conductive layers of the multilayer cylindrical capacitor can be formed with metal. In addition, cylindrical insulating layers of the multilayer cylindrical capacitor can be formed with a dielectric, such as a high k dielectric.

The via can be a through silicon via (TSV), a blind via or a Super via. In addition, the multilayer cylindrical capacitor can be coupled with other components, for example, a MOM capacitor, a MIM capacitor, or a MOS capacitor. another component coupled to the multilayer cylindrical capacitor.

Various aspect and features of the disclosure are described in further detail below.

### BRIEF DESCRIPTION OF THE FIGURES

The accompanying drawings are presented to aid in the description and illustrations of embodiments and are not intended to be limitations thereof.

FIGS. 1A through 1C are diagrams of various capacitor structures.

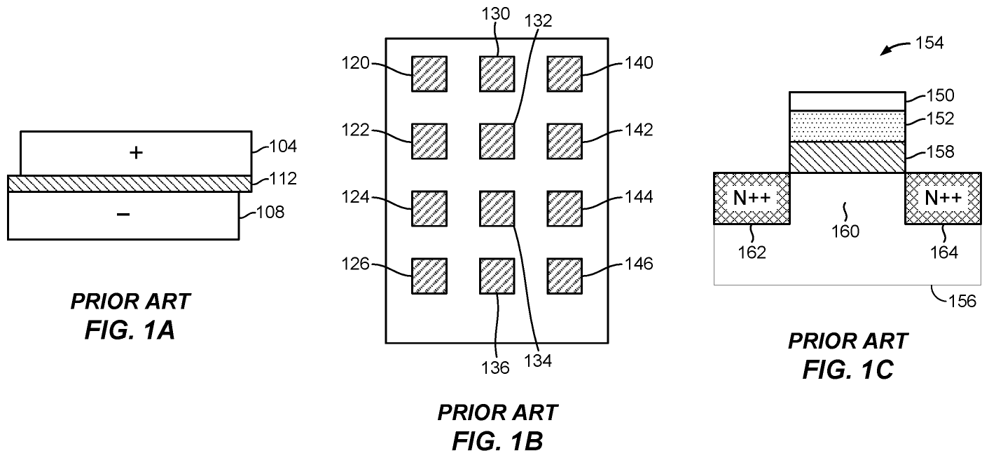

FIGS. 2A and 2B are diagrams of a through via coaxial capacitor.

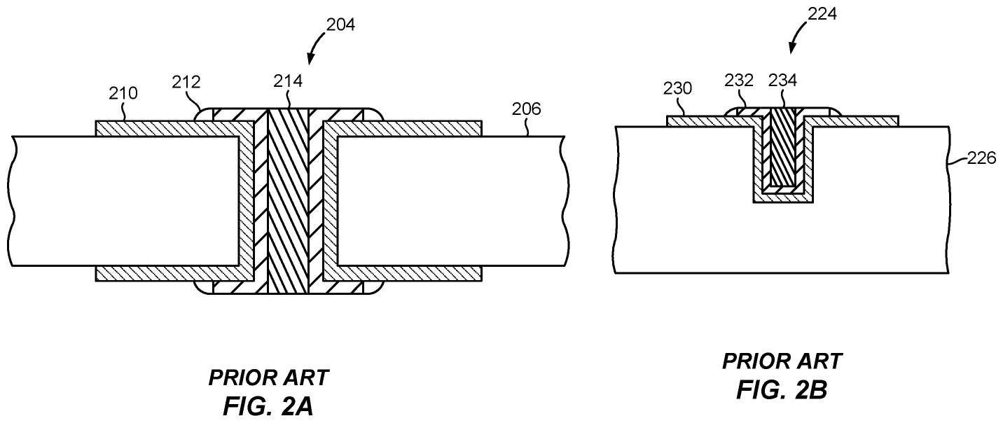

FIGS. 3A and 3B are diagrams of an embodiment of a multilayer cylindrical capacitor structure.

FIG. 4 is a diagram of an example electrical connections for a multilayer cylindrical capacitor structure formed in a blind via.

FIGS. 5A-5E are diagrams illustrating an example method of fabricating a multilayer capacitor structure.

FIGS. 6A and 6B illustrate an embodiment of a multilayer cylindrical capacitor structure formed in a through silicon via (TSV).

FIGS. 7A and 7B illustrate an embodiment of a multilayer cylindrical capacitor structure formed in a Supper via.

FIG. 8 is a diagram illustrating various circuit combinations that can be made using multilayer cylindrical capacitor structures.

The drawings may not depict all components of a particular apparatus, structure, or method. Further, like reference numerals denote like features throughout the specification and figures.

### DETAILED DESCRIPTION

Aspects disclosed in the following description and related drawings are directed to specific embodiments. Alternative embodiments may be devised without departing from the scope of the invention. Additionally, well-known elements may not be described in detail, or may be omitted, so as not to obscure relevant details. Embodiments disclosed may be suitably included in any electronic device.

With reference now to the drawing, several exemplary aspects of the present disclosure are described. The word “exemplary” is used herein to mean “serving as an example, instance, or illustration.” Any aspect described herein as “exemplary” is not necessarily to be construed as preferred or advantageous over other aspects. Furthermore, the terminology used herein is for the purpose of describing particular embodiments and is not intended to be limiting

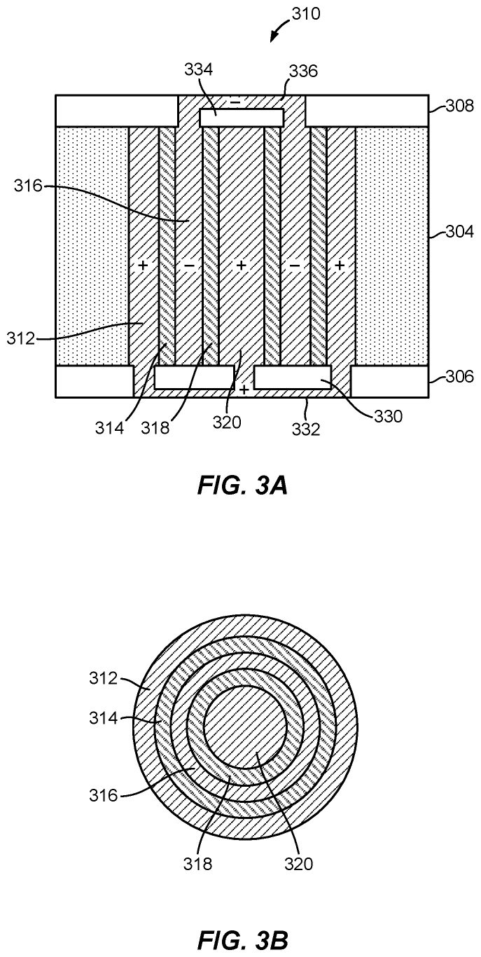

FIG. 3A is a cross section diagram of a multilayer cylindrical capacitor structure. FIG. 3B is a top view of the multilayer cylindrical capacitor structure. As shown in FIG. 3A, there is a substrate 304 with a first insulating layer 306 on a bottom surface of the substrate 304 and a second insulating layer 308 on a top surface of the substrate 304. Extending through the first and second insulating layers 306 and 308 and the substrate 304 is a via 310. The via 310 extending through the substrate and exposed on both sides is referred to as a via or through via, in another embodiment, explained further below, a multilayer cylindrical capacitor can be formed in a blind via that is exposed only on one end.

On the sidewalls of the via 310 a first cylindrical conductive layer 312 is formed. On an inner surface of the first cylindrical conductive layer 312 a first cylindrical insulating layer 314 is formed. On an inner surface of the first cylindrical insulating layer 314 a second cylindrical conductive layer 316 is formed. On an inner surface of the second cylindrical conductive layer 316 a second cylindrical insulating layer 318 is formed. On an inner surface of the second cylindrical insulating layer 318 a third cylindrical conductive layer 320 is formed that fills the remaining portion of the via 310.

As shown in FIG. 3B, the alternating cylindrical conductive layers 312, 316, and 320 and cylindrical insulating layers 314 and 318 form a multilayer cylindrical capacitor structure with the cylindrical conductive layers forming the plates of the capacitor. In the example of FIG. 3A there is an insulating layer 330 covering the bottom portion of the second conductive layer 316 and over the insulating layer 330 there is a conductive layer 332 coupling the first conductive layer 312 to the third conductive layer 320. On the top of the substrate 304 the insulating layer 308 extends over the first conductive layer 312 and there is an insulating layer 334 covering the third conductive layer 320, and over the insulating layer 324 there is a conductive layer 336 forming a coupling to the second conductive layer 316.

In the example of FIGS. 3A and 3B, three cylindric conductive layers separated by cylindrical insulating layers are illustrated, in other embodiments there may be more cylindrical conductive layers separated by cylindrical insulating layers. Also, the embodiment of FIG. 3 illustrates forming the multilayer cylindrical capacitor in a through via. In another embodiment, the multilayer cylindrical capacitor can be formed in a blind via. The multilayer cylindrical capacitor can also be formed in a through silicon via (TSV) or a Super via. A through silicon via (TSV) is a via that extends completely through a silicon wafer, or dia. A typical via couples adjacent metal layers, such as M_{X} layer to M_{X+1} layer. A Super via couples metal layers that are not adjacent, such as M_{X} layer to M_{X+n} layer where n>=2.

In one embodiment the conductive layers can be metal layers. In addition, the capacitor density can be further increased through the use of high K dielectric material as the insulating layers. In other embodiments, other insulating materials may be used, for example, HfO2, HfZrO2, AlNx, AlO2, or SiNx. An advantage of the multilayer cylindrical capacitor, such as the example of FIGS. 3A and 3B, is that the capacitance per unit area, or capacitor density, is increased over conventional via capacitors and it occupies less area then traditional MOM, MIM, and MOS capacitors.

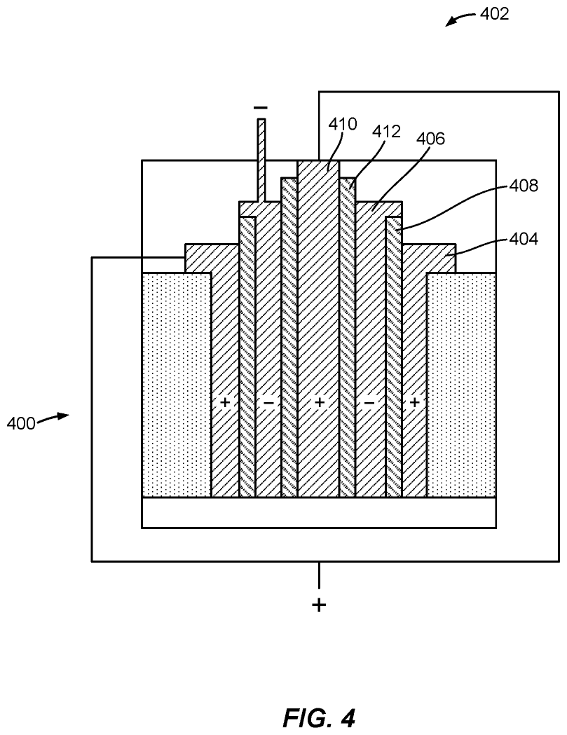

FIG. 4 is a diagram of an example electrical connections for a multilayer cylindrical capacitor structure formed in a blind via. As shown in FIG. 4, the multilayer cylindrical capacitor structure 400 is formed in a blind via 402. The multilayer cylindrical structure 400 includes a first cylindrical conductive layer 404 and a second cylindrical conductive layer 406 inside the first cylindrical conductive layer 404. The first and second cylindrical conductive layers 404 and 406 are separated by a first cylindrical insulating layer 408. The multilayer capacitor structure 400 further includes a third, cylindrical conductive layer 410 in the center of the blind via 402 and separated from the second cylindrical conductive layer 406 by a second cylindrical insulating layer 412. In the example of FIG. 4, the third cylindrical conductive layer 410 can be a solid cylinder, filling the remaining portion of the via. While the example illustrated in FIG. 4 shows three cylindrical conductive layers, other number of cylindrical conductive layers can be used.

In the example of FIG. 4 the first cylindrical conductive layer 404 and second cylindrical conductive layer 406 form plates of a first capacitor and the second cylindrical conductive layer 406 and third cylindrical conductive layer 410 form plates of a second capacitor. In the example of FIG. 4 the first and third cylindrical conductive layers 404 and 410 respectively, are connected to one voltage potential and the second cylindrical conductive layer 406 is connected to a different voltage potential, connecting the first and second capacitors in parallel. For example, the first voltage potential could be Vdd and the second voltage potential could be ground (GND).

In the example of FIG. 4, three cylindrical conductive layers are separated by cylindrical insulating layers, in other embodiments there may be more cylindrical conductive layers separated by insulating layers. In one embodiment, the conductive layers can be metal layers. In addition, in one embodiment the insulating layers can be a high K dielectric material. In other embodiments, other insulating materials may be used, for example, HfO2, HfZrO2, AlNx, AlO2, or SiNx.

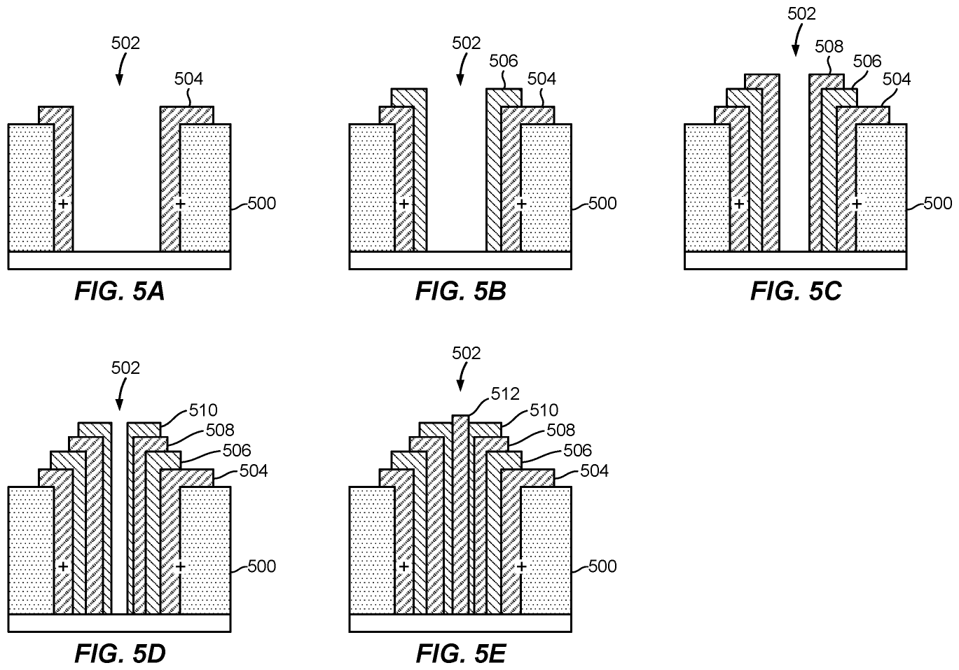

FIGS. 5A-5E are diagrams illustrating an example method of fabricating a multilayer capacitor structure. FIG. 5A shows a substrate 500 with a blind via 502. On an inner wall of the blind via 502 a first conductive cylindrical layer 504 is formed. In FIG. 5B, a first insulating cylindrical layer 506 is formed over an inner surface of the first conductive cylindrical layer 504. In FIG. 5C, a second conductive cylindrical layer 508 is formed over the first dielectric cylindrical layer 506. In FIG. 5D, a second insulating cylindrical layer 510 is formed on an inner surface of the second conductive cylinder layer 508. In FIG. 5E, a third conductive cylindrical layer 512 fills the remining portion of the via 502.

The conductive and insulating layers in FIGS. 5A-5D can be formed by self-aligned conformal growth, layer-by-layer, to form the multilayer cylindrical capacitor structure. In one embodiment, the conductive layers can be metal layers. In addition, in one embodiment the insulating layers can be a high K dielectric material. In other embodiments, other insulating materials may be used, for example, HfO2, HfZrO2, AlNx, AlO2, or SiNx.

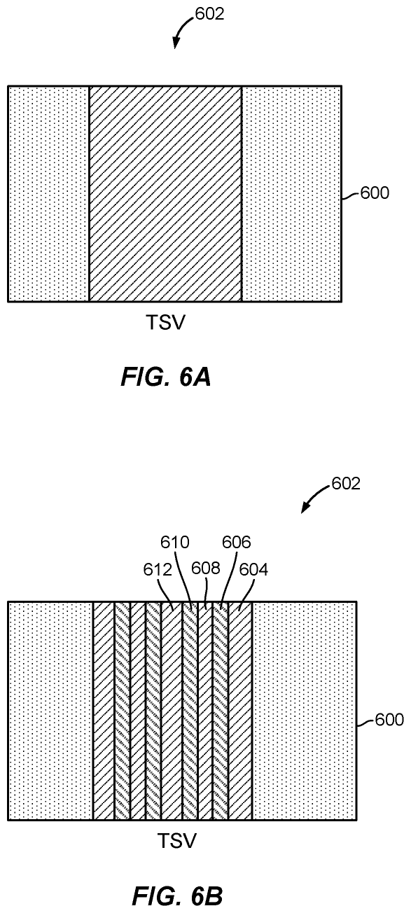

FIGS. 6A and 6B illustrate an embodiment of a multilayer cylindrical capacitor structure formed in a through silicon via (TSV). FIG. 6A shows a portion of a silicon wafer or die 600. A through silicon via (TSV) 602 is formed, extending through the entire portion of the silicon or die 600.

FIG. 6B illustrates forming a multilayer cylindric capacitor structure in the TSV 602. As shown in FIG. 6B, a first cylindrical conductive layer 604 is formed on an inner surface of the TSV 602. A first cylindrical insulating layer 606 is formed on an inner surface of the first cylindrical conductive layer 604. A second cylindrical conductive layer 608 is formed on an inner surface of the first cylindrical insulating layer 606. A second cylindrical insulating layer 610 is formed on an inner surface of the second cylindrical conductive layer 608. A third cylindrical conductive layer 612 is formed on an inner surface of the second cylindrical insulating layer 610 and fills the remaining portion of the TSV 602. In the example of FIGS. 6A and 6B the cylindrical conductive layers can be metal, and the cylindrical insulating layers can be a dielectric, such as a high K dielectric. In other embodiments, other insulating materials may be used, for example, HfO2, HfZrO2, AlNx, AlO2, or SiNx.

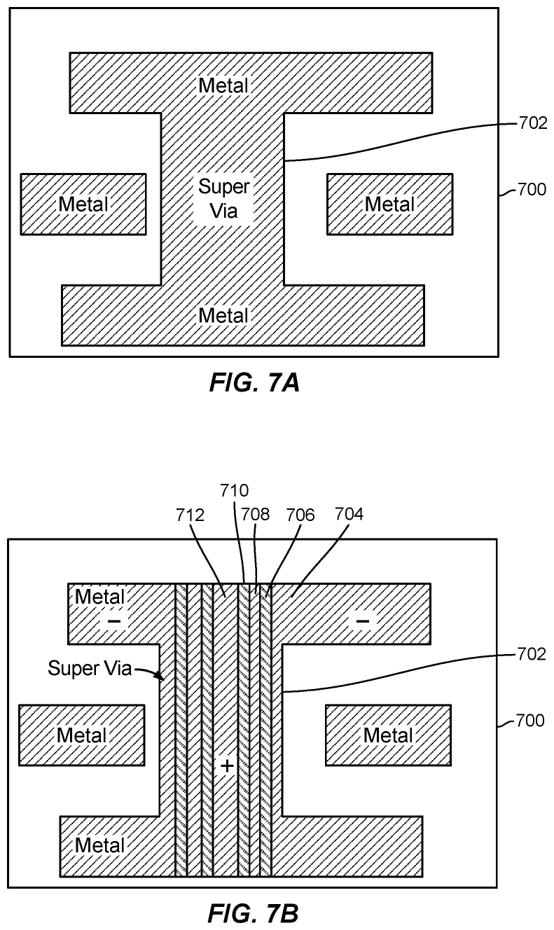

FIGS. 7A and 7B illustrate an embodiment of a multilayer cylindrical capacitor structure formed in a Supper via. FIG. 7A shows a portion of a substrate 700. A Super via 702, which is larger than a typical via, is formed, extending through a portion of the substrate 700.

FIG. 7B illustrates forming a multilayer cylindric capacitor structure in the Super via 702. As shown in FIG. 7B, a first cylindrical conductive layer 704 is formed on an inner surface of the Super via 702. A first cylindrical insulating layer 706 is formed on an inner surface of the first cylindrical conductive layer 704. A second cylindrical conductive layer 708 is formed on an inner surface of the first cylindrical insulating layer 706. A second cylindrical insulating layer 710 is formed on an inner surface of the second cylindrical conductive layer 708. A third cylindrical conductive layer 712 is formed on an inner surface of the second cylindrical insulating layer 710 and fills the remaining portion of the Super via 702. In the example of FIGS. 7A and 7B the cylindrical conductive layers can be metal, and the cylindrical insulating layers can be a dielectric, such as a high K dielectric. In other embodiments, other insulating materials may be used, for example, HfO2, HfZrO2, AlNx, AlO2, or SiNx.

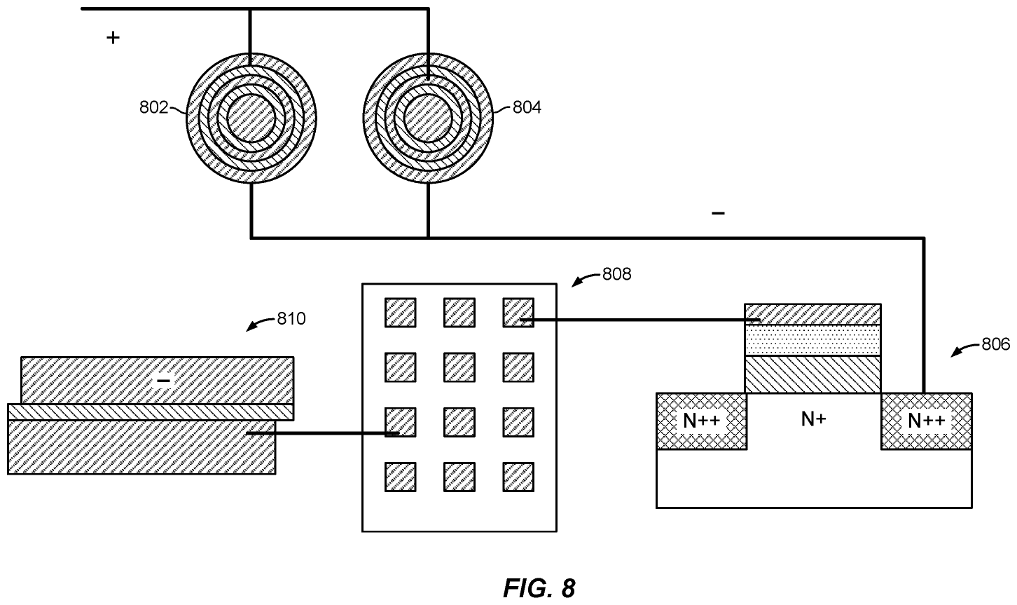

FIG. 8 is a diagram illustrating various circuit combinations that can be made using multilayer cylindrical capacitor structures. FIG. 8 illustrates a first and a second multilayer cylindrical capacitor 802 and 804 respectively. Also shown in FIG. 8 is a metal-oxide-silicon (MOS) capacitor 806, a metal-oxide-metal (MOM) capacitor 808, and a metal-insulator-metal (MIM) capacitor 810. The components illustrated in FIG. 8, as well as other components, can be arranged and couple to make various circuits.

In the example of FIG. 8, the first and second multilayer cylindrical capacitors 802 and 804 are coupled in parallel. The parallel combination of multilayer cylindrical capacitors 802 and 804 are coupled in series with the MOS capacitor 806 and MIM capacitor 808 and MIM capacitor 810. Other circuit configurations using multilayer cylindrical capacitors are possible.

The various illustrative logical blocks, modules, and circuits described in connection with the aspects disclosed herein may be implemented or performed in an integrated circuit (IC), a system on a chip (SoC), an Application Specific Integrated Circuit (ASIC), a Field Programmable Gate Array (FPGA) or other programmable logic device, discrete gate or transistor logic, discrete hardware components, or any combination thereof designed to perform the functions described herein.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in flow chart diagrams may be subject to numerous different modifications as will be readily apparent to one of skill in the art.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A multilayer cylindric capacitor comprising:
a substrate;
a via formed in the substrate;
a first cylindrical conductive layer formed on an inner surface of the via;
a first cylindrical insulating layer formed on an inner surface of the first cylindrical conductive layer;
a second cylindrical conductive layer formed on an inner surface of the first cylindrical insulating layer
a second cylindrical insulating layer formed on an inner surface of the second cylindrical conductive layer; and
a third cylindrical conductive layer formed on an inner surface of the second cylindrical insulating layer.

2. The multilayer cylindrical capacitor of claim 1, wherein the cylindrical conductive layers are metal.

3. The multilayer cylindrical capacitor of claim 1, wherein the cylindrical insulating layers are high k dielectric.

4. The multilayer cylindrical capacitor of claim 1, wherein the third cylindrical conducting layer fills a remaining portion of the via.

5. The multilayer cylindrical capacitor of claim 1, wherein the via is a through silicon via (TSV).

6. The multilayer cylindrical capacitor of claim 1, wherein the via is a blind via.

7. The multilayer cylindrical capacitor of claim 1, wherein the via is a Super via.

8. The multilayer cylindrical capacitor of claim 1, further comprising another component coupled to the multilayer cylindrical capacitor.

9. The multilayer cylindrical capacitor of claim 8, wherein the other component coupled to the multilayer cylindrical capacitor is a metal-oxide-metal (MOM) capacitor.

10. The multilayer cylindrical capacitor of claim 8, wherein the other component coupled to the multilayer cylindrical capacitor is a metal-insulator-metal (MIM) capacitor.

11. The multilayer cylindrical capacitor of claim 8, wherein the other component coupled to the multilayer cylindrical capacitor is a metal-oxide-silicon (MOS) capacitor.

12. A multilayer cylindric capacitor comprising:
a substrate;
a via formed in the substrate;
a plurality of cylindrical conductive layers and a plurality of cylindrical insulating layer formed inside the via;
wherein the plurality of cylindrical conductive layers are separated by the plurality of cylindrical insulating layers.

13. The multilayer cylindrical capacitor of claim 12, wherein the cylindrical conductive layers are metal.

14. The multilayer cylindrical capacitor of claim 12, wherein the cylindrical insulating layers are high k dielectric.

15. The multilayer cylindrical capacitor of claim 12, wherein the via is a through silicon via (TSV).

16. The multilayer cylindrical capacitor of claim 12, wherein the via is a Super via.

17. The multilayer cylindrical capacitor of claim 12, wherein the via is a blind via.

18. The multilayer cylindrical capacitor of claim 12, further comprising another component coupled to the multilayer cylindric capacitor.

19. A method of fabricating a multilayer cylindric capacitor comprising:
forming a via on a substrate;
forming a plurality of cylindrical conductive layers and a plurality of cylindrical insulating layer formed inside the via;
wherein the plurality of cylindrical conductive layers are separated by the plurality of cylindrical insulating layers.

20. The method of fabricating a multilayer cylindrical capacitor of claim 19, wherein the cylindrical conductive layers are metal.

21. The method of fabricating a multilayer cylindrical capacitor of claim 19, wherein the cylindrical insulating layers are high k dielectric.

22. The method of fabricating a multilayer cylindrical capacitor of claim 19, wherein the via is a through silicon via (TSV).

23. The method of fabricating a multilayer cylindrical capacitor of claim 19, wherein the via is a Super via.

24. The method of fabricating a multilayer cylindrical capacitor of claim 19, wherein the via is a blind via.
